(19) United States
(12) Patent Application Publication
(10) Pub. No.: US 2010/0301367 A1
(43) Pub. Date: Dec. 2, 2010

(54) LIGHT-EMITTING DEVICE COMPRISING A DOME-SHAPED CERAMIC PHOSPHOR

(75) Inventors: TOSHITAKA NAKAMURA, Oceanside, CA (US); Hironaka Fujii, Carlsbad, CA (US); Hiroaki Miyagawa, Oceanside, CA (US); Rajesh Mukherjee, Irvine, CA (US); Bin Zhang, San Diego, CA (US); Amane Mochizuki, San Diego, CA (US)

Correspondence Address: KNOBBE MARTENS OLSON & BEAR LLP, 2040 MAIN STREET, FOURTEENTH FLOOR, IRVINE, CA, 92614, US

(73) Assignee: NITTO DENKO CORPORATION, Osaka (JP)

(21) Appl. No.: 12/788,154

(22) Filed: May 26, 2010

Related U.S. Application Data
(60) Provisional application No. 61/183,025, filed on Jun. 1, 2009.

(51) Int. Cl. H01L 33/52

(52) U.S. Cl. 257/98; 257/E33.059

(57) ABSTRACT

Some embodiments provide a light-emitting device comprising: a light-emitting diode; a substantially transparent encapsulating material having a refractive index in the range of about 1.3 to about 1.8; a layer of low refractive index material having a refractive index in the range of about 1 to about 1.2; and a translucent ceramic phosphor having a refractive index in the range of about 1.6 to about 2.7, and is substantially dome-shaped with substantially uniform thickness. Some embodiments provide a light-emitting device comprising: a substrate; a light-emitting diode mounted on a surface of the substrate; and a substantially hemispheric cover mounted on the surface of the substrate so as to enclose the light emitting diode; wherein the substantially hemispheric cover comprises an outer layer, a middle layer, and an inner layer arranged concentrically, with the inner layer being nearest the light-emitting diode.

### CROSS-REFERENCE TO RELATED APPLICATIONS

This application claims the benefit of U.S. Provisional Application No. 61/183,025, filed Jun. 1, 2009, which is incorporated by reference herein in its entirety.

### BACKGROUND OF THE INVENTION

1. Field of the Invention

The present invention relates to a light-emitting device, such as a wavelength converted semiconductor light-emitting diode (LED) having dome-shaped translucent ceramic phosphor.

2. Description of the Related Art

White light-emitting diodes (LED) are well-known solid state lighting devices and have been widely put to practical use. Examples of uses of LEDs include indicators for various instruments, backlighting for LCD displays used in cellular phones, signboards, ornamental illumination, etc.

For some applications, it is difficult to obtain an LED which emits light in the color range desired for the application. For example, many LEDs emit blue light, but often white light is desired for a device. In these situations, phosphors can be used to change the color of the emitted light. This is done by allowing blue or some other colored light emitted from the LED to pass through the phosphor. Some of the light passes through the phosphor unaltered, but some of the light is absorbed by the phosphor, which then emits light of a different wavelength. Thus, the phosphor tunes the apparent color of the emitted light by converting part of the light to light of a different wavelength. Many white light-emitting devices are based upon this type of color conversion. For example, one type of conventional white-light emitting device comprises a blue-LED and yellow light emitting YAG phosphor powder dispersed in encapsulant resin such as epoxy or silicone. Recently, LED devices have been prepared which use a ceramic phosphor plate instead of a powder.

Although these developments have improved light-emitting diode devices, there is a continuing need to improve the efficiency of devices containing light-emitting diodes.

### SUMMARY OF THE INVENTION

Some embodiments provide a light-emitting device comprising: a light-emitting diode; a substantially transparent encapsulating material disposed to allow at least a portion of light from the light-emitting diode to pass through the encapsulating material, wherein the encapsulating material has a substantially dome-shaped outer surface and a refractive index in the range of about 1.3 to about 1.8 a layer of low refractive index material disposed to allow at least a portion of the light passing through the encapsulating material to pass through the layer of low refractive index material, wherein the low refractive index material has a refractive index of in the range of about 1 to about 1.2 and is substantially dome-shaped with substantially uniform thickness; and a translucent ceramic phosphor disposed to receive at least a portion of the light passing through the layer of low refractive index material and convert at least a portion of the light received to light of a different wavelength, wherein the ceramic phosphor has a refractive index in the range of about 1.6 to about 2.7, and is substantially dome-shaped with substantially uniform thickness.

Some embodiments provide a light-emitting device comprising: a substrate; a light-emitting diode mounted on a surface of the substrate; and a substantially hemispheric cover mounted on the surface of the substrate so as to enclose the light emitting diode; wherein the substantially hemispheric cover comprises an outer layer, a middle layer, and an inner layer arranged concentrically, with the inner layer being nearest the light-emitting diode; wherein the outer layer is of substantially uniform thickness and comprises a translucent ceramic phosphor having a refractive index in the range of about 1.6 to about 2.7; the middle layer is of substantially uniform thickness and comprises a material having a refractive index in the range of about 1 to about 1.2; and the inner layer is a silicone resin having a refractive index in the range of about 1.35 to about 1.8; and wherein the translucent ceramic phosphor is configured to convert at least a portion of light emitted from the light-emitting diode to light of a different wavelength.

These and other embodiments are described in greater detail below.

### BRIEF DESCRIPTION OF THE DRAWINGS

FIGS. 1A-C illustrates some embodiments of “substantially hemispheric.”

FIG. 2 illustrates some embodiments of “substantially hemispheric.”

FIGS. 3A-B illustrates some embodiments of height and diameter in some embodiments of “substantially hemispheric” shape.

FIG. 4 illustrates an exemplary embodiment of the devices disclosed herein.

FIGS. 5A-C illustrates an exemplary embodiment of a method of preparing embodiments of devices disclosed herein.

FIGS. 6A-D illustrates additional exemplary embodiments of the devices disclosed herein.

FIGS. 7A-D illustrates additional exemplary embodiments of the devices disclosed herein.

FIG. 8 illustrates additional exemplary embodiments of the devices disclosed herein.

FIG. 9 illustrates additional exemplary embodiments of the devices disclosed herein.

FIG. 10 illustrates an embodiment of a casting die set that may be used to prepare embodiments of the dome-shaped ceramic phosphor disclosed herein.

FIG. 11 illustrates the optical configuration used to measure total light transmittance of the devices prepared as described in Examples 1 and 2 and Comparative Example 1.

FIG. 12 shows emission spectra of the devices prepared as described in Examples 1 and 2 and Comparative Example 1.

The Figures are not to scale.

### DETAILED DESCRIPTION OF THE PREFERRED EMBODIMENTS

Some embodiments disclosed herein provide a light-emitting device comprising a light-emitting diode and a substantially dome-shaped translucent ceramic phosphor; wherein the phosphor is disposed to receive at least a portion of light emitted from the light-emitting diode and convert at least a portion of the light received to light of a different wavelength.

The term “substantially dome-shaped” has the ordinary meaning understood by those of ordinary skill in the art, and may include a substantially hemispheric shape. Some embodiments provide a device comprising a light-emitting diode (LED) which is enclosed by a substrate and a substantially hemispheric cover. In some embodiments, the LED is mounted onto a surface of the substrate. In some embodiments the substantially hemispheric cover is mounted onto the surface of the substrate so as to enclose the LED. In some embodiments, the substantially hemispheric cover is disposed to receive emissions from the LED. In some embodiments the substantially hemispheric cover is positioned adjacent the substrate and the LED, with the LED interposed between the substrate and the substantially hemispheric cover.

In some embodiments, the substantially hemispheric cover may comprise an outer layer, a middle layer, and an inner layer arranged concentrically, with the inner layer being nearest the light-emitting diode. In some embodiments, the substantially hemispheric cover may consist essentially of the outer layer, the middle layer, and the inner layer arranged concentrically, with the inner layer being nearest the light-emitting diode. In some embodiments, the substantially hemispheric cover may be configured to reduce loss of light caused by total internal reflection of the light within the outer layer as compared to an otherwise substantially identical device comprising a translucent ceramic phosphor which is not substantially hemispheric. In some embodiments, the outer layer and the middle layer are of “substantially uniform thickness,” which refers to the situation where the thickness of a layer is substantially consistent throughout the layer.

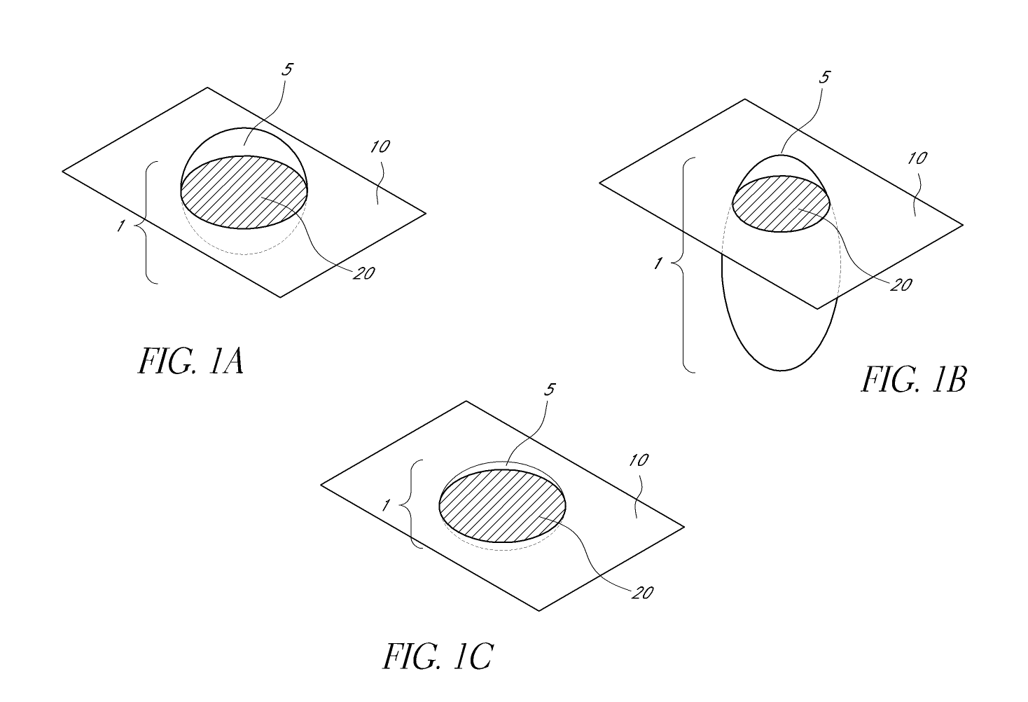

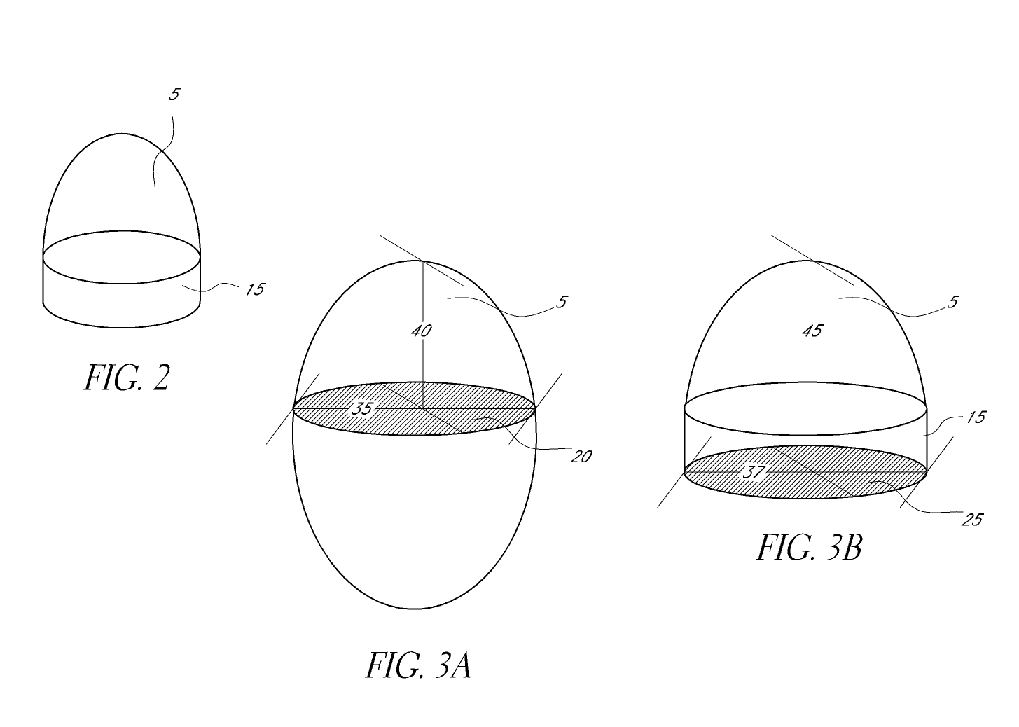

Turning to FIG. 1, in some embodiments, the cover is “substantially hemispheric,” meaning that the surface of the cover is approximately the smaller shape 5 obtained when a spheroid 1 is cut by a plane 10. The spheroid may be a sphere such as in FIG. 1A, a prolate spheroid such as in FIG. 1B, an oblate spheroid such as in FIG. 1C, etc. Alternatively, in some embodiments, as shown in FIG. 2, the cover is “substantially hemispheric” if it comprises a cylinder 15 with the smaller shape 5 at the top of the cylinder 15. There may be some variations, such as roughness, unevenness, holes, or texture, in the surface as long as the general substantially hemispheric shape would be recognizable to one of ordinary skill in the art. In some embodiments, the substantially hemispheric cover comprises a circular base, meaning that, with reference to any figure including FIG. 3A, the shape 20 formed by the intersection of the plane with the spheroid 1 is a circle.

In some embodiments, as shown in FIG. 3A, the term “height” refers to the distance 40 from the plane cutting the spheroid to the top of the smaller shape 5. In some embodiments, the term “diameter” refers to the longest distance across shape 20. In some embodiments, as shown in FIG. 3B, the term “height” refers to the distance 45, from the plane at the base of the cylinder 10 to the top of the smaller shape 5. In some embodiments, the term “diameter” refers to the diameter 37 of the base of the cylinder 25. In some embodiments, the height/diameter ratio of the substantially spherical cover is in the range of about 0.2 to about 2, about 0.3 to about 0.8, about 0.4 to about 0.6, or alternatively about 0.5. In some embodiments, the substantially hemispheric cover has a diameter in the range of about 4 mm to about 9 mm.

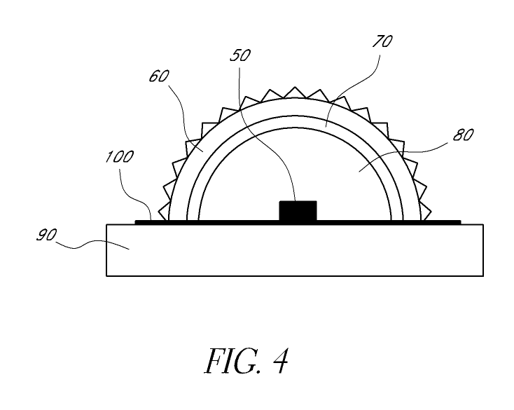

While many structures are contemplated, FIG. 4 depicts an exemplary embodiment comprising an LED 50 which is surrounded by an inner layer 80 comprising substantially transparent encapsulating material. The encapsulating material of this embodiment is surrounded by a middle layer 70 comprising a low refractive index material. The middle layer 70 of this embodiment is then surrounded by an outer layer 60 comprising a translucent ceramic phosphor. The outer layer 60 of this embodiment has texture. The LED 50 of this embodiment is mounted on a reflective surface 100 of a substrate 90.

In some embodiments, the outer layer of the light-emitting device may comprise a translucent ceramic phosphor. The refractive index of the ceramic phosphor layer may depend on phosphor material used. In some embodiments, the refractive index of the outer layer may be in the range of about 1.6 to about 2.7, about 1.65 to about 2.2, or alternatively, about 1.70 to about 2.0. If (Y₁₋ₓCeₓ)₃Al₅O₁₂ is used as a phosphor material, the refractive index may be about 1.83 at a wavelength of about 800 nm. In some embodiments, the translucent ceramic phosphor is represented by represented by a formula such as, but not limited to (A₁₋ₓEₓ)₃D₅O₁₂, (Y₁₋ₓEₓ)₃D₅O₁₂; (Gd₁₋ₓEₓ)₃D₅O₁₂; (La₁₋ₓEₓ)₃D₅O₁₂; (Lu₁₋ₓEₓ)₃D₅O₁₂; (Tb₁₋ₓEₓ)₃D₅O₁₂; (A₁₋ₓEₓ)₃Al₅O₁₂; (A₁₋ₓEₓ)₃Ga₅O₁₂; (A₁₋ₓEₓ)₃In₅O₁₂; (A₁₋ₓCeₓ)₃D₅O₁₂; (A₁₋ₓEuₓ)₃D₅O₁₂; (A₁₋ₓTbₓ)₃D₅O₁₂; (A₁₋ₓEₓ)₃Nd₅O₁₂; and the like. In some embodiments, the ceramic comprises a garnet, such as a yttrium aluminum garnet, with a low dopant concentration. Some embodiments provide a composition represented by the formula (Y₁₋ₓCeₓ)₃Al₅O₁₂. In any of the above formulas, A may be Y, Gd, La, Lu, Tb, or a combination thereof; D may be Al, Ga, In, or a combination thereof; E may be Ce, Eu, Tb, Nd, or a combination thereof; and x may be in the range of about 0.0001 to about 0.005, from about 0.0001 to about 0.001, or alternatively, from about 0.0001 to about 0.002.

In some embodiments, the translucent ceramic phosphor may be disposed to receive at least a portion of the light passing through the layer of low refractive index material, or middle layer, and convert at least a portion of the light received to light of a different wavelength. As used herein, the phrase “convert at least a portion of the light,” or an equivalent expression, is intended to refer to a situation where a portion of the light is absorbed by the ceramic phosphor, and the ceramic phosphor then emits light of a different color. Thus, the conversion of a portion of the light provides tuning of the color. In some embodiments, the translucent ceramic phosphor may absorb blue light and emit yellow light. For example, in some embodiments, the ceramic has a wavelength of maximum absorbance in the range of about 420 nm to about 480 nm, and a wavelength of maximum emission in the range of about 500 nm to about 750 nm, about 500 nm to about 700 nm, or alternatively, about 500 nm to about 600 nm.

In some embodiments, the translucent ceramic phosphor may be made thicker to increase the amount of light emitted from the light-emitting diode which is converted to light of a different wavelength. Thus, the observed light will appear less like the color of the light-emitting diode and more like the color of the ceramic. Alternatively, the translucent ceramic phosphor may be made thinner to decrease the amount of converted light, thus making the color appear more similar to that of the light-emitting diode. For example, in the case that the light-emitting diode emits blue light and the translucent ceramic phosphor is yellow, or emits yellow light, a thinner ceramic may yield light which appears more blue, and a thicker ceramic may yield light which appears more white or yellow. In some embodiments, the translucent ceramic phosphor has a thickness in the range of about 50 μm to about 5 mm, about 0.2 mm to about 2 mm, or alternatively, about 0.1 mm to about 1 mm.

As mentioned above, the color of the emitted light may depend upon the thickness of the translucent ceramic phosphor or the outer layer. In some embodiments, the thickness of the ceramic phosphor layer is sufficiently thin that consistent thickness may be difficult to maintain. Thus, in some embodiments, consistent color may be difficult to achieve. Therefore, in some embodiments, the ceramic phosphor may comprise at least one hole through the ceramic phosphor. In some embodiments, the number of holes may be adjusted to achieve the desired color. In some embodiments, more holes may be added to make the light more blue. In some embodiments, fewer holes may be used to make the light more yellow or white. The hole or holes may also be useful in reducing the loss of light due to total internal reflection by the outer layer.

In some embodiments, the outer layer of the light-emitting device comprises an outer surface, wherein at least a portion of the outer surface has a texture. For example, in some embodiments, the texture may have a depth in the range of about 0.5 μm to about 100 μm. In some embodiments, the outer surface having texture may be useful in reducing the loss of light due to total internal reflectance by the outer layer. In some embodiments, the texture may comprise a regular or patterned microstructure. In some embodiments, the regular or patterned microstructure has a repeating period of about 100 μm, or alternatively about 10 μm, or less. In some embodiments the texture of the surface of the ceramic phosphor may create a microsurface which may be about normal to the hemispheric surface. In some embodiments, the texture of the surface creates a microsurface which is at an angle to the hemispheric surface such that total internal reflection is interrupted. In some embodiments, texture comprises concave and/or convex portions formed on the outer surface of the outer layer or ceramic phosphor. In some embodiments, these convex or concave portions may be randomly distributed over the outer surface. In some embodiments, these concave or convex portions may be periodically or regularly distributed over the outer surface. In some embodiment, an average period of the concave and convex portions may be about 100 μm or less, or alternatively, 10 μm or less.

Any projected shape of the concave and convex portions on the outer surface may be utilized. In some embodiments, the projected shape can be circular, ovoid, a waveform, a trapezoid, a rectangle, a triangle, etc. In some embodiments, a plurality of shapes may be combined. Any cross sectional shape of the concave and convex portions on the outer surface may be utilized. In some embodiments, the cross section may be a waveform, a trapezoid, a rectangle, a triangle, etc. In some embodiments, a plurality of shapes may be combined. It is also possible to use a construction in which the surface is made rough by allowing particles to agglomerate on the outside of a mold during fabrication. In some embodiments, the texture of the outer surface effects an increase in light intensity between the wavelengths of 500 nm to 550 nm of at least 25%, at least 30%, at least 40%, at least 50% over the light intensity emitted by a conventional LED having phosphor powder comprising a substantially similar material as the material of the outer surface suspended in a transparent material (e.g., YAG powder suspended in epoxy resin).

The ceramic phosphor may be substantially transparent or translucent. However, in some instances small defects in the ceramic phosphor, such as air voids, may cause backscattering loss of light from a light-emitting diode. Normally, the number of defects in a ceramic phosphor material is small, and the backscattering loss is minimal. However, in some instances, since the number of defects may be small, it may difficult to obtain consistent scattering levels in the ceramic phosphor. Thus, in some embodiments, additional defects may be added which may increase the scattering, but may provide better consistency in the scattering from one ceramic phosphor to another. In some embodiments, the total light transmittance of the ceramic phosphor, measured at about 800 nm, is greater than or equal to about 50%, or alternatively about 60%, to about 70%, or alternatively about 80%. In some embodiments, additional scattering may be provided by controlling air void density or alien crystal phase growth (non-polycrystalline phase material). In some embodiments, the ceramic phosphor further comprises a second component, e.g., at least a second ceramic material. In some embodiments, the second ceramic material is selected from at least one of: yttrium aluminum garnet powder; amorphous powders comprising yttrium, aluminum, oxygen, and/or cerium; YAlO₃:Ce; Al₂O₃ powders; alumina; yttria; and yttrium aluminum oxide.

In some embodiments, the middle layer of the light-emitting device may comprise a low refractive index material. The phrase “low refractive index material” is intended to indicate material having an index of refraction less than the material of the outer layer and the material of the inner layer. In some embodiments the middle layer or low refractive material is disposed between the LED and the outer layer. In some embodiments, the middle layer or low refractive material is disposed between the outer layer and the inner layer. In some embodiments, the middle layer is adjacent the outer layer. In some embodiments, at least part of the middle layer is in contact with the inner surface of the outer layer, creating an interface between the inner surface of the outer layer and the middle layer. In some embodiments, this may increase the amount of total internal reflection of converted light occurring at the interface between the outer layer and the middle layer. This increased total internal reflection combined with the reduced internal reflection at the outer surface, as effected by the textured surface, increases the amount of light extracted from the outer layer. Thus, disposition of the middle layer between the outer layer and the inner layer can provide increased extraction of light from the outer layer. The middle layer or low refractive index material may be disposed so that light passes through it coming from the encapsulating material or inner layer and going to the outer layer or translucent ceramic phosphor. The refractive index of the middle layer may be in the range of about 1 to about 1.2, about 1 to about 1.1, or alternatively, about 1 to about 1.05. The material may be any material having a low refractive index, such as an inert or compatible gas. For example, air, nitrogen, argon, carbon dioxide, and combinations thereof, are examples of inert or compatible gases that have low refractive indexes. In some embodiments, the low refractive index material comprises air. In some embodiments, the middle layer comprises a porous material which may include an inert or compatible gas such as air in the pores. In some embodiments, the middle layer comprises a resin comprising a plurality of hollow spheres which may include an inert or compatible gas within the spheres. In some embodiments, the middle layer comprises a foam plastic layer. In some embodiments, the middle layer has a thickness in the range of about 0.001 mm to about 2 mm, about 0.003 mm to about 0.1 mm, about 0.005 mm to about 0.05 mm. In some embodiments, as a result of combining a middle layer of lower refractive index material and a roughened outer surface, the light intensity of emitted light between 500 and 550 nm may be increased at least about 3%, at least about 5%, at least about 7% or at least about 10% over combinations with just a ceramic element with a roughened outer surface.

In some embodiments, the inner layer of the light-emitting device may be a substantially transparent encapsulating material. In some embodiments, the encapsulating material may be a resin, such as epoxy resin, acrylic resin, silicone resin, polyurethane resin, polyamide resin, polyimide resin, etc. In some embodiments, the inner layer may fill the space between the LED and the middle layer or the layer of low refractive index material. In some embodiments, at least a portion of the light emitted from the LED passes through the inner layer to the middle layer. In some embodiments, the refractive index of the inner layer or encapsulating material may be in the range of about 1.30 to about 1.80, about 1.30 to about 1.55, about 1.35 to about 1.55, or alternatively, about 1.40 to about 1.55.

In some embodiments, the middle layer of the light-emitting device further comprises a second phosphor material which is dispersed in the substantially transparent encapsulating material, e.g., in the resin. Any phosphor material may be used, including organic and inorganic phosphor materials, such as any of the ceramic phosphor materials disclosed herein. In one embodiment, the phosphor material comprises a plurality of nano-sized particles dispersed in the encapsulating material, the nano-sized particles having an average particle size in the range of about from 5 nm to about 30 nm. In some embodiments, the nano-sized particles have a refractive index in the range of about 1.8 to about 2.72. In some embodiments, the plurality of nanoparticles has a volume which is in the range of about 1% to about 30% of the volume of the inner layer or the encapsulating material.

Any light-emitting diode, including organic or inorganic LEDs, may be used. In some embodiments, the LED is mounted on a substrate and disposed or encapsulated by the substantially hemispheric cover so that at least a portion of the light passes through the inner layer or encapsulating material, the middle layer or low refractive index layer, and the outer layer or translucent ceramic phosphor. In some embodiments, at least a portion of the light traveling into the outer layer or translucent ceramic phosphor is absorbed and emitted as light of a different wavelength, thus effecting a color change for the light emitted by the device. The light emitted by the LED may be any color, including blue, green, yellow, orange, red, etc. In some embodiments, the LED emits light having a wavelength of maximum emission in the range of about 440 nm to about 470 nm.

In some embodiments, the LED is mounted on the surface of a substrate. In some embodiments, the substrate is substantially planar. In another embodiment, the substrate may comprise a depression defined in a planar member, or a cup member comprising a wall extending upwards from a bottom member to define a cavity therein. Thus, in some embodiments, the LED may be completely enclosed, with the substrate acting as the bottom of the device and the substantially hemispheric cover completely covering the LED. In some embodiments, at least a portion of the surface of the substrate is reflective. This may be useful to improve recycling of the light radiated toward the substrate. In some embodiments, the surface reflects more than about 80%, more than about 90, or alternatively, more than 98% of the light that contacts the surface. The surface may be any type of reflective surface, including a diffusive or a specular reflective surface. In some embodiments, this reflective portion of the surface of the substrate may help to reduce loss due to backscattering from the layers of the substantially hemispheric cover.

There are many methods generally known in the art that may be applied to prepare the ceramic phosphors which may be used for the outer layer. In some embodiments, the ceramic phosphors are prepared by methods such as commonly known ceramic body fabrication procedures, including molded ceramic green compact preparation. In some embodiments, conventional molded ceramic compact manufacturing processes using ceramics raw powders with properly added polymer-based binder materials and/or flux (such as SiO₂ and/or MgO), dispersant, and/or solvent may be employed. In some embodiments, particle size may be important. For example, if the particle size becomes too large, it may become difficult to achieve a highly dense ceramic, which may be desirable, because large particles may not easily agglomerate or fuse to each other, even at a high sintering temperature. Furthermore, increased particle size may increase the number of air voids in the ceramic layer. On the other hand, smaller nano-sized particles may have an increased ability to fuse with one another, which may result in highly dense and air void-free ceramic elements. In some embodiments, the raw powders used to prepare ceramic phosphors may be nano-sized particles with an average particle size no greater than about 1000 nm, or alternatively, no greater than about 500 nm.

In some embodiments, binder resin, dispersant, and/or solvent may be added to the raw powder during mixing and/or molding to facilitate the fabrication process. In some embodiments, the mixing process may employ equipment such as a mortar and pestle, a ball milling machine, a bead milling machine, etc. In some embodiments, the molding process utilizes methods such as simple die pressing, monoaxial pressing, hot isostatic pressing (HIP), and cold isostatic pressing (CIP). In some embodiments, to control the thickness of ceramic layer, controlled quantities of raw powders are loaded in a mold followed by applying pressure. In some embodiments, to control the thickness of ceramic shell, controlled quantities of raw powders may be loaded in a mold followed by applying pressure. In some embodiments, slip casting of slurry solution may be utilized to make a molded ceramic green compact. In some embodiments, the substantially hemispheric shape may be prepared via punching and press work by using a flexible ceramic green sheet prepared by a tape casting method as widely employed in the multi-layer ceramic capacitor manufacturing process.

In some embodiments, an outer surface having texture of the ceramic phosphor may be prepared by a replication technique which uses a mold with a surface having texture. In some embodiments, the method for forming the texture of the surface may include: performing a polishing or abrading step on the surface of the ceramic phosphor to produce a textured surface. In some embodiments, a photolithography and etching technique may be used to form a regularly or periodically rabbet surface. In some embodiments, the surface has a roughness in the range of about 0.5 microns to about 100 microns. In some embodiments, a mold having a blast finish in a predetermined area may be used to form the texture of the surface of the ceramic phosphor. In embodiments where a texture of a surface may be prepared by a surface treating process, the texture of a surface may be controlled by varying the particle size of the abrasive and/or the processing time. In embodiments where a texture of a surface is prepared by painting an ink that includes a light diffusing agent, the light diffusing level may be controlled by varying the kind, the particle size, and/or the concentration of the light diffusing agent.

In some embodiments, the substantially hemispheric molded ceramic green body may be heat treated in an oxygen atmosphere, such as air, to remove binder resin or any other residues. The heat-treating may be carried out at any temperature higher than the temperature at which the decomposition of the binder resin starts, but lower than the temperature at which the pores on the surface of the sample are closed off. In some embodiments, the heat-treating may comprise heating at a temperature in the range of 500° C. to 1000° C. for a time in the range of about 10 min to about 100 hr. The conditions may depend on binder resin decomposition speed, and may be adjusted to prevent warping and/or a deformation of ceramic green body.

Next, in some embodiments, sintering may be performed under a controlled atmosphere to provide void-free ceramic phosphors. The sintering temperature range typically depends on the ceramic material being sintered, the average particle size of raw powder, and the density of ceramic green compact. In some embodiments, e.g., where the ceramic comprises YAG:Ce, the sintering temperature may be in the range of about 1450° C. to about 1800° C. While any suitable sintering ambient condition may be employed, in some embodiments, the sintering ambient may be a vacuum; an inert gas such as helium, argon, and nitrogen; or a reducing gas such as hydrogen or mixture of hydrogen and inert gas.

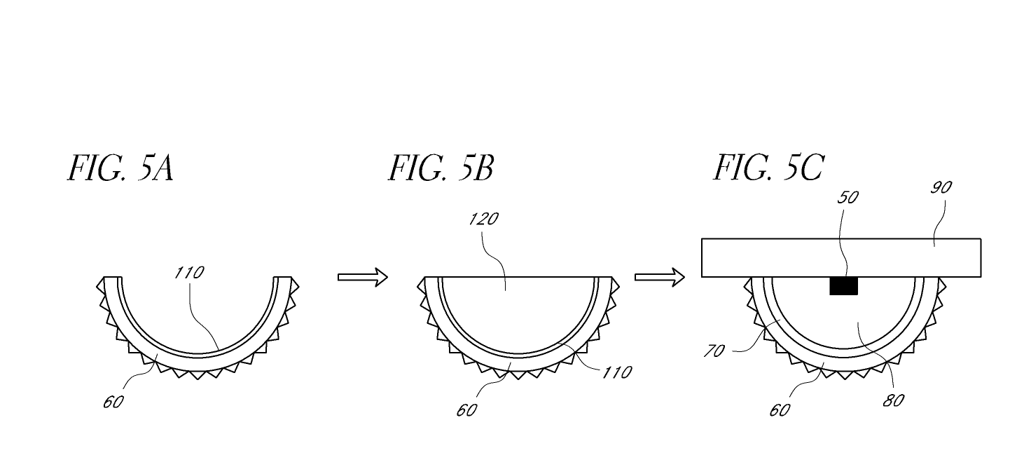

While these devices may be made by any number of methods known in the art, FIG. 5 depicts one method that may be useful to prepare some embodiments of the devices. In this method, a foaming material 110, which is capable of emitting a gas at about the curing temperature of an encapsulating resin or material, is deposited onto the inner surface of a dome-shaped ceramic phosphor 60. Next, an encapsulant resin solution 120 is deposited onto the foaming material 110 so that it fills the volume of the ceramic phosphor 60. Finally, an LED chip 50 with substrate 90 is substantially aligned so that the chip 50 is centered as illustrated. The encapsulant resin is then cured at its curing temperature. In this step, curing of the encapsulant resin and expansion of foaming material can proceed concurrently. As a result, the substantially uniform middle layer 70 comprising low refractive index material and the substantially dome-shape of encapsulant resin 80 are constructed at the same time.

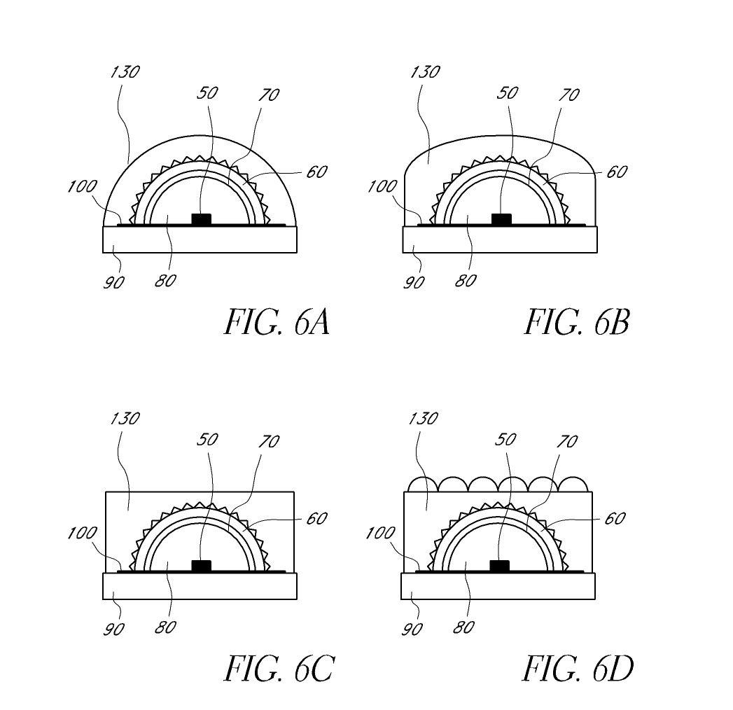

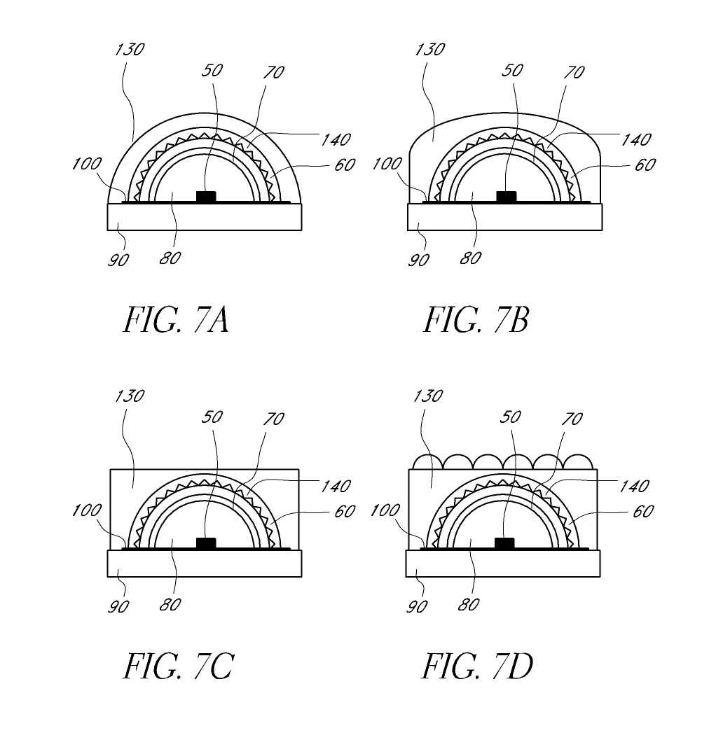

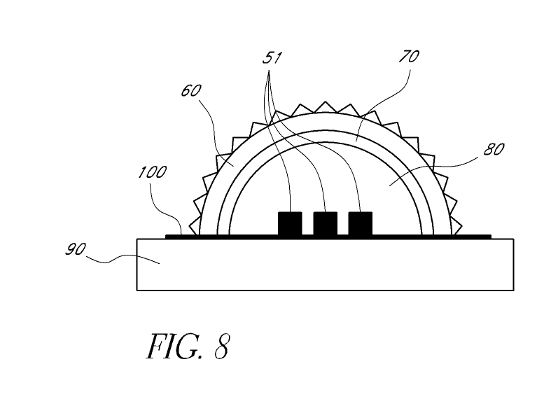

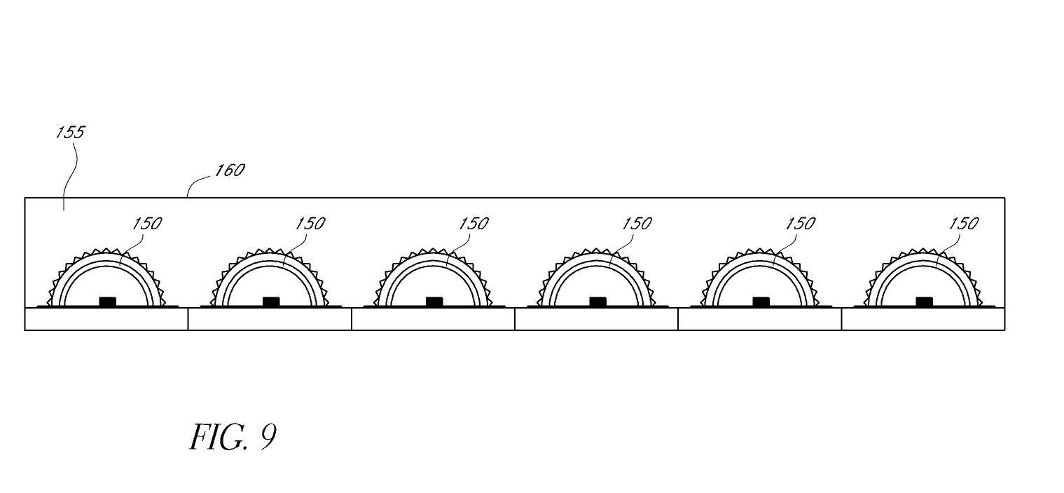

In some embodiments, further molded material 130 can be fabricated on the outside of outer layer 60, as shown in FIG. 6. In some embodiments, a low refractive index gap 140 may be also formed at any position between the ceramic dome 60 and the molded material 130 as shown in FIG. 7. In some embodiments, as depicted in FIG. 8, a multi-LED chip array 51 can be utilized. In some embodiments, as depicted in FIG. 9, a plurality of devices 150 may be encapsulated within a single piece of material 155 to form a single device 160.

### Example 1

Ce doped YAG powder (12 g, average particle size≅130 nm), poly(vinyl butyral-co-vinyl alcohol-co-vinyl acetate, Sigma-Aldrich) (0.9 g, average Mw=90,000-120,000 powder, Sigma-Aldrich, St. Louis, Mo., USA), fumed silica powder (0.036 g, CAB-O-SIL® HS-5, Cabot Corporation, Boston, Mass., USA), and methanol (˜30 ml) were mixed by using ball milling for 5 hours. The slurry thus obtained was screened out by using 32 μm mesh. Dried powder was obtained by blowing hot air from a dryer and continually moving the pestle until the methanol was completely removed.

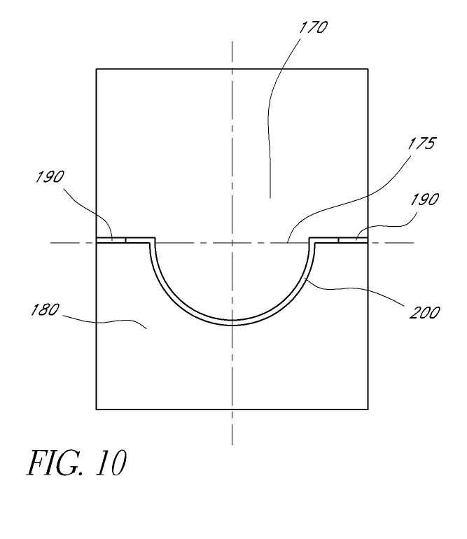

The powder was put into the die set illustrated in FIG. 10. As shown in FIG. 10, the die set comprises a convex piece 170, which comprises a convex member 175 which is substantially a hemisphere having a radius of about 4 mm. Two spacers 190 are placed near the edge of the convex piece 170 which meet a concave piece 180, and provide a space 200 in the shape of a hemispheric shell having a radius of about 4 mm and a thickness of about 300 μm when pressure is applied. A sufficient amount of powder was placed in the space 200 to allow sufficient pressure to be applied before the convex piece 170 and the concave piece 180 meet the spacers 190. A pressure of 5000 psi was applied between the concave piece 180 and the convex piece 170 using hydraulic press at room temperature to obtain a dome-shaped ceramic green compact.

The convex surface of the obtained dome-shaped ceramic green compact was textured by using sandpaper (South Bay Technology, San Clemente, Calif., USA, Silicon Carbide Paper #120). This operation was done with extra care to prevent the dome-shaped green compact from being broken. Then, the textured dome-shaped ceramic green compact was heat treated at 800° C. (heating rate was 4° C./min) for 1 hr in air in order to remove binder resin. The ceramic compact was then sintered at 1600° C. (heating rate was 2° C./min) for 5 hours in a vacuum. A yellow-colored translucent YAG:Ce ceramic dome was obtained.

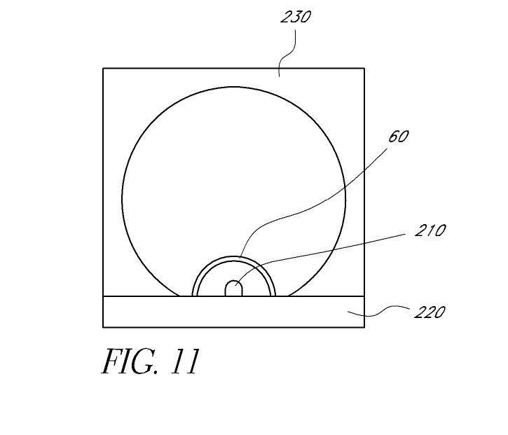

Total light transmittance of the dome was measured by using the optical configuration illustrated in FIG. 11. Since the ceramic phosphor 60 can absorb light impinging upon it if the impinging light is within a specific wavelength region, the point-like light source 210 whose emission wavelength of light is outside of this absorptive wavelength was used for this measurement. For example, a red-LED (about 660 nm) was used for these measurements. In order to avoid retroreflection, the point-like light source 210 was placed onto a black body surface 220. The emission intensity of the light source 210 was first measured by using an integrating sphere 230 without the ceramic phosphor 60. The ceramic phosphor 60 was then placed as shown in FIG. 11 and the emission intensity was measured under the same driving conditions of light source as the previous measurement. Total light transmittance was calculated by comparing the data from the two measurements to be 77% at 660 nm (Red-LED chip was used as light source).

Silicone gel viscous solution was then poured into the ceramic dome using a pipette. As shown in FIG. 5, a submount (which acts as substrate 90 in this particular embodiment) with a 1 mm² blue-LED chip (which acts as LED 50 in this particular embodiment) was carefully placed onto the dome-shaped ceramic phosphor prepared above (which acts as the outer layer 60 in this particular embodiment) while making sure that no air bubbles were incorporated between the LED chip and silicone gel (which acts as encapsulating material 80 in this particular embodiment). Then, this sample was heated at 150° C. for 2 hours in order to cure the silicone gel.

### Example 2

The same procedure was followed as that described for Example 1 except for the following. Before the silicone gel viscous solution was poured into the ceramic dome by using a pipette, heat-expandable microspheres (Matsumoto Microsphere F-50D, Matsumoto Yushi-Seiyaku Co., Ltd., Osaka, JPN) including acrylic pressure-sensitive adhesive solution of ethyl acetate were coated onto the inner surface of the obtained ceramic dome by using a cotton-tipped swab in order to form a porous, low refractive index layer after curing at 150° C. for 2 hours.

### Comparative Example 1

Casting type epoxy resin (0.4 g) was mixed with commercial YAG:Ce phosphor powder (0.6 g, Kasei Optonix, Ltd. Odawara City, JPN, P46-Y3) was mixed. The mixture was mounted onto the same type of blue LED chip used in Example 1, and cured at 135° C. for 2 hours.

A LED device with commercial YAG:Ce phosphor powder was driven under the same conditions described in Example 1, and white colored emission was observed.

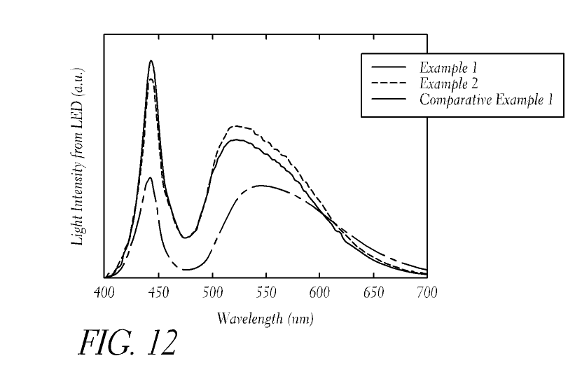

LED Performance Test The three LED devices prepared in Examples 1 and 2 and Comparative Example 1 were driven by an electrical current source with DC 25 mA. Emission spectrum was acquired by using a photo detector together with an integrating sphere (MCPD 7000, Otsuka Electronics, Inc., Osaka, JPN). FIG. 12 shows an emission spectra from each LED device with dome-shape ceramic phosphor. Compared to the LED device which is encapsulated by using conventional phosphor powder dispersed resin in Comparative Example 1, LEDs with ceramic dome in Example 1 and 2 showed stronger light emission. In FIG. 12, the peak light intensity of the emission within the 500 to 550 nm wavelengths was about 0.0646 for Comparative Example 1; 0.097 for Example 1 and 0.107 for Example 2. Thus, Example 1 (roughened surface only) had a 50% increase in light intensity over the comparative example. In addition, an LED with ceramic dome with a roughened outer surface and a middle layer of lower refractive index material (Example 2) had about 10% brighter light intensity between about 475 and about 550 nm than the light intensity of the LED with ceramic dome (roughened surface only) of Example 1. Greater emission in this range may be useful since the light emitted within the those wavelengths correspond with blue light. Thus, these dome-shaped translucent ceramic phosphors may be useful for generating white light in combination with yellow emitters or alternatively, other red and green emitters.

What is claimed is:

1. A light-emitting device comprising:
a light-emitting diode;
a substantially transparent encapsulating material disposed to allow at least a portion of light from the light-emitting diode to pass through the encapsulating material, wherein the encapsulating material has a substantially dome-shaped outer surface and a refractive index in the range of about 1.3 to about 1.8
a layer of low refractive index material disposed to allow at least a portion of the light passing through the encapsulating material to pass through the layer of low refractive index material, wherein the low refractive index material has a refractive index of in the range of about 1 to about 1.2 and is substantially dome-shaped with substantially uniform thickness; and
a translucent ceramic phosphor disposed to receive at least a portion of the light passing through the layer of low refractive index material and convert at least a portion of the light received to light of a different wavelength, wherein the ceramic phosphor has a refractive index in the range of about 1.6 to about 2.7, and is substantially dome-shaped with substantially uniform thickness.

2. The light-emitting device of claim 1, wherein the ceramic phosphor has an outer surface having a texture.

3. The light-emitting device of claim 2 wherein the texture has a depth in the range of about 0.5 μm to about 100 μm.

4. The light-emitting device of claim 1, wherein the ceramic phosphor comprises a composition represented by a formula (A₁₋ₓEₓ)₃D₅O₁₂,
wherein A is Y, Gd, La, Lu, Tb, or a combination thereof;
x is in the range of from about 0.0001 to about 0.005;
D is Al, Ga, In, or a combination thereof; and
E is Ce, Eu, Tb, Nd, or a combination thereof.

5. The light-emitting device of claim 4 wherein A is Y, D is Al, and the ceramic phosphor comprises a garnet structure.

6. The light-emitting device of claim 5 wherein E is Ce.

7. The light-emitting device of claim 6, wherein x is in the range of about 0.0001 to about 0.002.

8. The light-emitting device of claim 1, wherein the light-emitting diode emits light having a wavelength of maximum emission in the range of about 440 nm to about 470 nm and the ceramic phosphor converts at least a portion of the light received to light having a wavelength of maximum emission in the range of about 500 nm to about 700 nm.

9. The light-emitting device of claim 1, wherein the ceramic phosphor has a thickness in the range of about 0.1 mm to about 1 mm.

10. The light-emitting device of claim 1, wherein the low refractive index material comprises air.

11. The light-emitting device of claim 1, wherein the ceramic phosphor comprises at least one hole through the ceramic phosphor.

12. The light-emitting device of claim 1, wherein the resin further comprises a second phosphor which is dispersed in the resin.

13. A light-emitting device comprising:
a substrate;
a light-emitting diode mounted on a surface of the substrate; and
a substantially hemispheric cover mounted on the surface of the substrate so as to enclose the light emitting diode;
wherein the substantially hemispheric cover comprises an outer layer, a middle layer, and an inner layer arranged concentrically, with the inner layer being nearest the light-emitting diode;
wherein the outer layer is of substantially uniform thickness and comprises a translucent ceramic phosphor having a refractive index in the range of about 1.6 to about 2.7;
the middle layer is of substantially uniform thickness and comprises a material having a refractive index in the range of about 1 to about 1.2; and
the inner layer is a silicone resin having a refractive index in the range of about 1.35 to about 1.55;
wherein the translucent ceramic phosphor is configured to convert at least a portion of light emitted from the light-emitting diode to light of a different wavelength.

14. The light-emitting device of claim 13, wherein the substantially hemispheric cover has a height to diameter ratio in the range of about 0.2 to about 2.

15. The light-emitting device of claim 13, wherein the substantially hemispheric cover has a diameter in the range of about 4 mm to about 9 mm.

16. The light-emitting device of claim 13, wherein the outer layer has a thickness in the range of about 0.1 mm to about 1 mm.

17. The light-emitting device of claim 13, wherein the middle layer has a thickness in the range of about 0.001 mm to 2 mm.

18. The light-emitting device of claim 13, wherein the outer layer comprises an outer surface, wherein at least a portion of the outer surface has a texture.

19. The light-emitting device of claim 13, wherein the substantially hemispheric cover is configured to reduce loss of light caused by total internal reflection of the light within the outer layer as compared to an otherwise substantially identical device comprising a translucent ceramic phosphor which is not substantially hemispheric.

20. The light-emitting device of claim 13, wherein the substantially hemispheric cover consists essentially of the outer layer, the middle layer, and the inner layer arranged concentrically, with the inner layer being nearest the light-emitting diode.
